(19) United States
(12) Patent Application Publication
(10) Pub. No.: US 2025/0102580 A1
(43) Pub. Date: Mar. 27, 2025

(54) CALIBRATION SYSTEM AND METHOD FOR SOC AND SOH IN AN ENERGY STORAGE SYSTEM

(71) Applicant: SIMPLO TECHNOLOGY CO., LTD., Hsinchu County (TW)

(72) Inventors: Ya-Mei CHANG, Hsinchu County (TW); Chi-Yang CHENG, Hsinchu County (TW); Chun-Chang CHEN, Hsinchu County (TW); Chia-Wei CHEN, Hsinchu County (TW)

(73) Assignee: SIMPLO TECHNOLOGY CO., LTD., Hsinchu County (TW)

(21) Appl. No.: 18/418,683

(22) Filed: Jan. 22, 2024

(30) Foreign Application Priority Data
Sep. 21, 2023 (TW) 112136111

(51) Int. Cl. G01R 31/367; G01R 31/388; G01R 31/392; H02J 7/00

(52) U.S. Cl. CPC G01R 31/367; G01R 31/388; G01R 31/392; H02J 7/0048; H02J 7/005; H02J 7/007186

(57) ABSTRACT

A calibration system and a calibration method for state of charge (SOC) and state of health (SOH) in an energy storage system are provided. The calibration system includes a Main Battery Management System (MBMS) and a plurality of racks, wherein, when the MBMS determines that one of the plurality of racks meets auto-calibration conditions, the MBMS utilizes a battery feature value extraction algorithm to obtain feature value data of each of battery packs, and predicts the number of battery cycles for each of the battery packs via a battery aging correction model. In this way, the SOC and the SOH for each of the battery packs can be accurately calculated, so that maintenance personnel can clearly comprehend the status of each of the racks, thereby improving the efficiency of power management.

### BACKGROUND

### 1. Technical Field

The present disclosure relates to a calibration technology for an energy storage system, and more particularly, to a calibration system and method for SOC (state of charge) and SOH (state of health) in an energy storage system.

### 2. Description of Related Art

In order to lessen global warming and achieve the goal of sustainable development, renewable energy has become the trend of energy development around the world. Meanwhile, under the promotion of renewable energy development regulations in countries around the world, the renewable energy development will be increasingly applied from offshore wind power generation and solar power generation in the future. However, considering that the unstable factors of renewable energy can impact the power grid and cause power outages and other accidents, countries have successively promulgated renewable energy smoothing regulations to limit the rate of change in renewable energy power. Governments also actively promote the developments of renewable energy and power trading markets, thus an energy storing system (hereinafter an energy storage system) has received considerable attention.

The indispensable main role in the energy storage system is the battery. In practice, multiple battery packs need to be presented in series or in parallel since the voltage and capacity of cells in a single battery cannot meet the requirements of the energy storage system. When multiple batteries are connected in series and parallel to form a battery pack, an imbalance phenomenon will occur due to the capacity difference and electrical characteristics of each battery cell, and this phenomenon will have a serious impact on the life of the battery pack, so it is necessary to monitor and control the capacity status of each cell. At this time, calibrations of state of charge (SOC) and state of health (SOH) become important parts.

In this regard, when using the energy storage system, a good mechanism is needed to estimate the state of charge (SOC) of each cell, so that the cell can be appropriately charged and discharged so as to avoid errors in the state of charge (SOC) and the state of health (SOH) of the battery. At the same time, the calibration mechanism and method are used to ensure that the battery pack will not be damaged or dangerous due to overcharging or over-discharging.

The state of charge (SOC) and the state of health (SOH) of the battery are indicators that designers and users care about, and related calculation methods such as Coulomb counting is one of the methods. Coulomb counting integrates the current flowing into or out of a battery unit to calculate the total charge flowing through the battery unit, thereby estimating the relative state of charge (SOC) change within a given time. However, there are still errors (such as battery temperature, battery aging) in the state of charge (SOC) based on Coulomb counting, which lead to inaccurate estimation of the initial value. Therefore, it is necessary to determine whether to calibrate the state of charge (SOC) of Coulomb counting regularly or irregularly to ensure the accuracy of the state of charge (SOC). Many patents have proposed improvement methods for the abovementioned solutions to the state of charge (SOC) errors, such as:
1. For the impact of battery temperature, such as choosing appropriate rest time or heating and cooling the battery before reading the voltage and weighting to correct the state of charge (SOC) and the state of health (SOH) of the battery.
2. For the impact of battery aging, the state of charge (SOC) and the state of health (SOH) of the battery are corrected with weights via the battery impedance database and statistics of measured direct current (DC) or alternating current (AC) impedance and usage times.

Although the aforementioned methods can improve the errors of the state of charge (SOC), the battery must be limited to stopped state, fully charged state, or reverse discharge state, so the aforementioned methods are still far from meeting the requirements for providing accurate state of charge (SOC) and state of health (SOH) in real time.

Therefore, how to provide a calibration technology of an energy storage system that can accurately estimate and calibrate the state of charge (SOC) and the state of health (SOH) of the battery has become an urgent problem to be solved for the industry.

### SUMMARY

In view of the aforementioned shortcomings of the prior art, the present disclosure provides a calibration system for state of charge (SOC) and state of health (SOH) in an energy storage system, the calibration system comprises: a power conversion system configured for providing power; a plurality of racks electrically connected to the power conversion system and obtaining the power from the power conversion system, wherein each of the plurality of racks comprises a plurality of battery packs; and a main battery management system communicatively connected to the plurality of racks and having a battery aging correction model, wherein when the main battery management system determines that one of the plurality of racks meets auto-calibration conditions, the main battery management system has the one of the plurality of racks disconnect from the power conversion system and obtains battery voltages and battery currents of each of the plurality of battery packs of the one of the plurality of racks, wherein the main battery management system executes a battery feature value extraction algorithm to obtain corresponding feature value data based on the battery voltages and the battery currents of each of the plurality of battery packs, so as to predict battery cycles of each of the plurality of battery packs based on the feature value data of each of the plurality of battery packs via the battery aging correction model, thereby calculating a corresponding SOH value based on the battery cycles of each of the plurality of battery packs and updating the plurality of battery packs.

The present disclosure further provides a calibration method for state of charge (SOC) and state of health (SOH) in an energy storage system, the calibration method comprises: when a main battery management system determines that one of a plurality of racks meets auto-calibration conditions, the main battery management system has the one of the plurality of racks disconnect from a power conversion system to obtain battery voltages and battery currents of each of the plurality of battery packs of the one of the plurality of racks; the main battery management system executes a battery feature value extraction algorithm to obtain corresponding feature value data based on the battery voltages and the battery currents of each of the plurality of battery packs; the main battery management system predicts battery cycles of each of the plurality of battery packs based on the feature value data of each of the plurality of battery packs via a battery aging correction model; and the main battery management system calculates a corresponding SOH value based on the battery cycles of each of the plurality of battery packs, and updates the plurality of battery packs.

In the aforementioned embodiment, the present disclosure further comprises a calibration device configured for providing a constant current, wherein after the one of the plurality of racks is disconnected from the power conversion system, the main battery management system has the one of the plurality of racks electrically connect to the calibration device, such that the one of the plurality of racks obtains the constant current from the calibration device.

In the aforementioned embodiment, the feature value data of each of the plurality of battery packs comprise a plurality of SOC feature values and a plurality of peak feature values.

In the aforementioned embodiment, the battery aging correction model predicts a plurality of possible cycles of each of the plurality of battery packs respectively based on the plurality of SOC feature values and the plurality of peak feature values of each of the plurality of battery packs, and further selects the battery cycles of each of the plurality of battery packs from the plurality of possible cycles of each of the plurality of battery packs.

In the aforementioned embodiment, the main battery management system calculates a plurality of peak SOC values of each of the plurality of battery packs based on the battery cycles of each of the plurality of battery packs and further calculates SOH values of each of the plurality of battery packs based on the plurality of peak SOC values of each of the plurality of battery packs.

In the aforementioned embodiment, the battery aging correction model is a neural network model.

It can be seen from the above that, in the calibration system and method for SOC and SOH in an energy storage system according to the present disclosure, the present disclosure can accurately obtain the feature value data of the plurality of battery packs via the battery feature value extraction algorithm, and accurately predict the battery cycles of each of the plurality of battery packs via the battery aging correction model that is based on a neural network. Therefore, the present disclosure can instantly calculate accurate state of charge (SOC) and state of health (SOH), so that maintenance personnel can quickly and clearly comprehend the status of each rack, thereby improving the efficiency of power management.

### BRIEF DESCRIPTION OF THE DRAWINGS

FIG. 1 is a schematic framework diagram showing a calibration system for state of charge and state of health in an energy storage system according to the present disclosure.

FIG. 2 is a flowchart showing a calibration method for state of charge and state of health in an energy storage system according to the present disclosure.

FIG. 3 is a flowchart showing a calibration method of a rack of the present disclosure.

FIG. 4A shows battery voltages of a battery pack of the present disclosure.

FIG. 4B shows battery currents of a battery pack of the present disclosure.

FIG. 5 shows feature value data of a battery pack of the present disclosure.

FIG. 6 shows a training data set of a battery aging correction model of the present disclosure.

FIG. 7 is a diagram showing an embodiment of a battery aging correction model of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “one,” “a,” “first,” “second,” “on,” “under,” and the like are merely used for clear explanation rather than limiting the practicable scope of the present disclosure, and thus, alterations or adjustments of the relative relationships thereof without essentially altering the technical contents should still be considered in the practicable scope of the present disclosure.

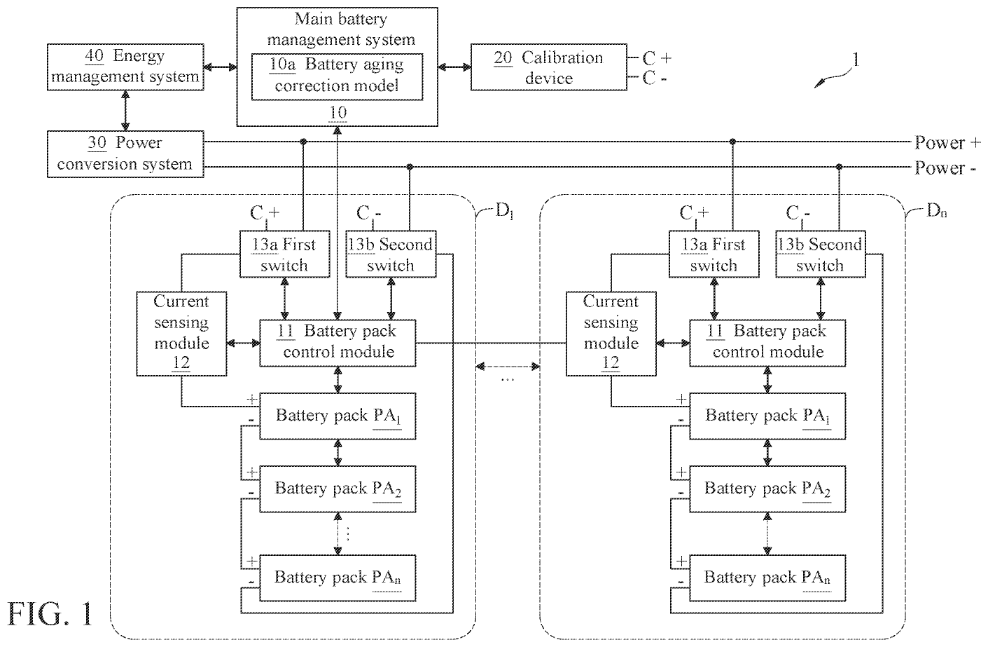

FIG. 1 is a schematic framework diagram showing a calibration system 1 for state of charge (SOC) and state of health (SOH) in an energy storage system according to the present disclosure, the calibration system 1 comprises: a main battery management system (MBMS) 10 with a battery aging correction model 10a and a plurality of racks D₁-Dₙ, wherein each of the plurality of racks D₁-Dₙ comprises a battery pack control module 11, a current sensing module 12, a first switch 13a, a second switch 13b and a plurality of battery packs PA₁-PAₙ. Besides, the calibration system 1 for state of charge and state of health in an energy storage system further comprises: a calibration device 20, a power conversion system 30 and an energy management system 40.

In specific, the calibration device 20 and the power conversion system 30 can be power supply devices, and the main battery management system 10 and the energy management system 40 can be established in back-end electronic devices with appropriate mechanisms such as servers (e.g., general servers, file servers, storage unit servers, etc.) and computers, wherein each module or model in the main battery management system 10 and the energy management system 40 can be software, hardware, or firmware; if it is hardware, it can be a processing unit, a processor, a computer, or a server with data processing and computing capabilities; if it is software or firmware, it can include executable instructions of a processing unit, a processor, a computer, or a server, and can be installed on the same hardware device or distributed to different plurality of hardware devices.

In an embodiment, the main functions of the power conversion system (PCS) 30 are as follows: (1) energy conversion and regulation, converting DC to AC for use by the power grid or load; (2) current and voltage stability, monitoring and controlling the currents and voltages of the energy storage system to ensure that the current and voltage are within a safe and stable range, thereby preventing abnormal conditions such as too high or too low voltages; (3) stabilizing the power grid frequency; (4) improving the energy storage efficiency.

In an embodiment, the main functions of the energy management system (EMS) 40 are as follows: (1) energy power control and monitoring; (2) energy power optimization; (3) energy storage system management; (4) fault detection, the energy management system can intelligently monitor and control energy flow to help achieve efficient utilization and comprehensive management of energy so as to reduce energy waste and ensure the stability of energy supply.

Moreover, in the plurality of racks D₁-Dₙ, the current sensing module 12 can be an ammeter, the first switch 13a and the second switch 13b can be relays, each of the plurality of battery packs PA₁-PAₙ comprises a plurality of batteries, and the plurality of batteries can be lithium iron phosphate batteries (LFP), nickel cadmium batteries (Ni—Cd), nickel metal hydride batteries (Ni-MH), or lithium ion batteries (Li-Ion), etc., and there is no limit to the battery types and battery combinations of the plurality of battery packs PA₁-PAₙ. In addition, the battery pack control module 11 can be software, hardware, or firmware; if it is hardware, it can be a processing unit with data processing and computing capabilities; if it is software or firmware, it can include executable instructions of a processing unit, a processor, a computer, or a server, and can be installed on the same hardware device or distributed to different plurality of hardware devices.

In an embodiment, as shown in FIG. 1, the main battery management system 10 is communicatively connected to the battery pack control module 11 of the plurality of racks D₁-Dₙ, the calibration device 20 and the energy management system 40; the energy management system 40 is communicatively connected to the power conversion system 30; the plurality of racks D₁-Dₙ are communicatively connected to each other; and the plurality of racks D₁-Dₙ are electrically connected to the power conversion system 30.

Furthermore, in each of the plurality of racks D₁-Dₙ, the battery pack control module 11 is communicatively connected to the current sensing module 12, the first switch 13a, the second switch 13b and the plurality of battery packs PA₁-PAₙ, and the plurality of battery packs PA₁-PAₙ are connected to each other in series, and the first switch 13a is electrically connected to a positive voltage terminal (Power+) within the power conversion system 30, and the second switch 13b is electrically connected to a negative voltage terminal (Power−) within the power conversion system 30, such that the plurality of racks D₁-Dₙ obtain power from the power conversion system 30, wherein the first switch 13a is connected to the current sensing module 12 in series, and the current sensing module 12 is connected to the positive terminal of one of the plurality of battery packs PA₁-PAₙ in series, and the negative terminal of another one of the plurality of battery packs PA₁-PAₙ is connected in series back to the second switch 13b, thereby forming a charge and discharge loop.

Additionally, another contact of the first switch 13a is electrically connected to a positive terminal C+ of the calibration device 20, and another contact of the second switch 13b is electrically connected to a negative terminal C− of the calibration device 20, so that a constant current is obtained from the calibration device 20 when the plurality of racks D₁-Dₙ are calibrated.

In an embodiment, the main battery management system 10 directly obtains the rack data from the plurality of racks D₁-Dₙ, or the main battery management system 10 obtains the other rack data of the plurality of racks D₁-Dₙ via one of the plurality of racks D₁-Dₙ, wherein the rack data comprise: battery voltages of the plurality of battery packs PA₁-PAₙ measured by a voltage sensing module (not shown) within the plurality of racks D₁-Dₙ, rack currents measured by the current sensing module 12 within the plurality of racks D₁-Dₙ, and battery temperatures of the plurality of battery packs PA₁-PAₙ measured by a temperature sensing module (not shown) within the plurality of racks D₁-Dₙ, but not limited to as such.

In an embodiment, the main battery management system 10 calculates the state of charge (SOC) of each battery within each of the battery packs PA₁-PAₙ based on the rack data of the plurality of racks D₁-Dₙ, wherein the main battery management system 10 can calculate the state of charge (SOC) of each battery within each of the plurality of battery packs PA₁-PAₙ by methods such as Euclidean distance prediction, Kalman filter prediction, etc. based on the rack data of the plurality of racks D₁-Dₙ.

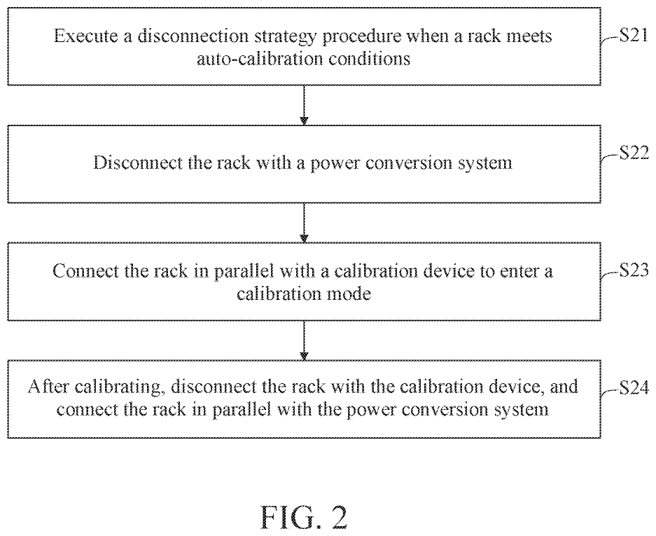

FIG. 2 is a flowchart showing a calibration method for state of charge and state of health in an energy storage system according to the present disclosure, and FIG. 2 is illustrated with reference to FIG. 1.

In step S21, the main battery management system 10 checks whether the plurality of racks D₁-Dₙ meet auto-calibration conditions, and when at least one (one or multiple) of the plurality of racks D₁-Dₙ meets the auto-calibration conditions, executing a disconnection strategy procedure.

In an embodiment, the auto-calibration conditions comprise but not limited to threshold of the rack current, threshold of the state of charge (SOC) of the battery, total power requirements, etc., and when the plurality of racks D₁-Dₙ do not meet the auto-calibration conditions, the main battery management system 10 executes a normal operating procedure, such as estimating the state of charge (SOC) of the plurality of racks D₁-Dₙ.

In step S22, when the main battery management system 10 determines that one of the plurality of racks D₁-Dₙ meets the auto-calibration conditions, the main battery management system 10 has the first switch 13a and the second switch 13b activate via the battery pack control module 11 of one of the plurality of racks D₁-Dₙ so as to disconnect the electrical connection between the positive voltage terminal (Power+) and the negative voltage terminal (Power−) of the power conversion system 30, that is, one of the plurality of racks D₁-Dₙ is disconnected from the power conversion system 30.

In step S23, the main battery management system 10 has the first switch 13a and the second switch 13b activate via the battery pack control module 11 of one of the plurality of racks D₁-Dₙ so as to conduct the electrical connection between the positive terminal (C+) and the negative terminal (C−) of the calibration device 20, that is, the calibration device 20 is connected in parallel with one of the plurality of racks D₁-Dₙ, and the calibration device 20 provides a constant current to one of the plurality of racks D₁-Dₙ, thereby calibrating one of the plurality of racks D₁-Dₙ.

In step S24, after one of the plurality of racks D₁-Dₙ has completed the calibration, the main battery management system 10 executes a connection in parallel strategy procedure, wherein the main battery management system 10 has the first switch 13a and the second switch 13b activate via the battery pack control module 11 of one of the plurality of racks D₁-Dₙ so as to disconnect the calibration device 20 and conduct the power conversion system 30, so that one of the plurality of racks D₁-Dₙ is connected in parallel with the power conversion system 30.

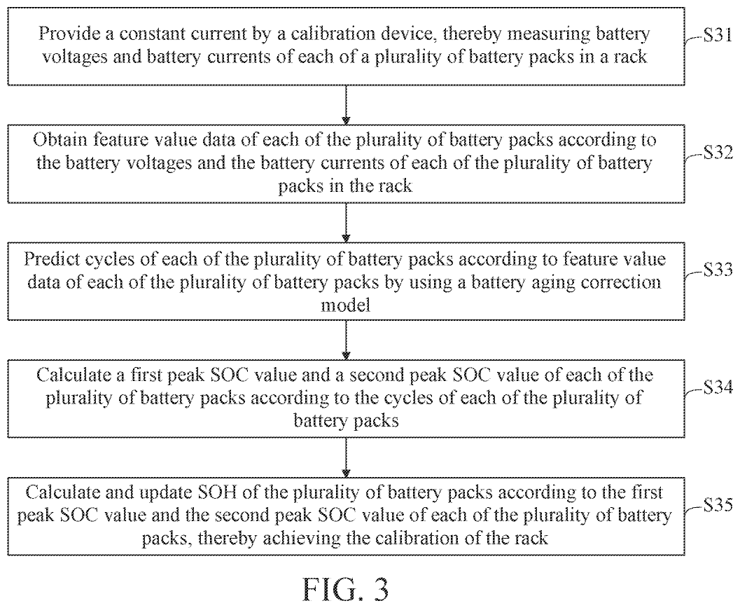

FIG. 3 is a flowchart showing a calibration method of the aforementioned rack of the present disclosure, and FIG. 3 is illustrated with reference to FIG. 1 and FIG. 2.

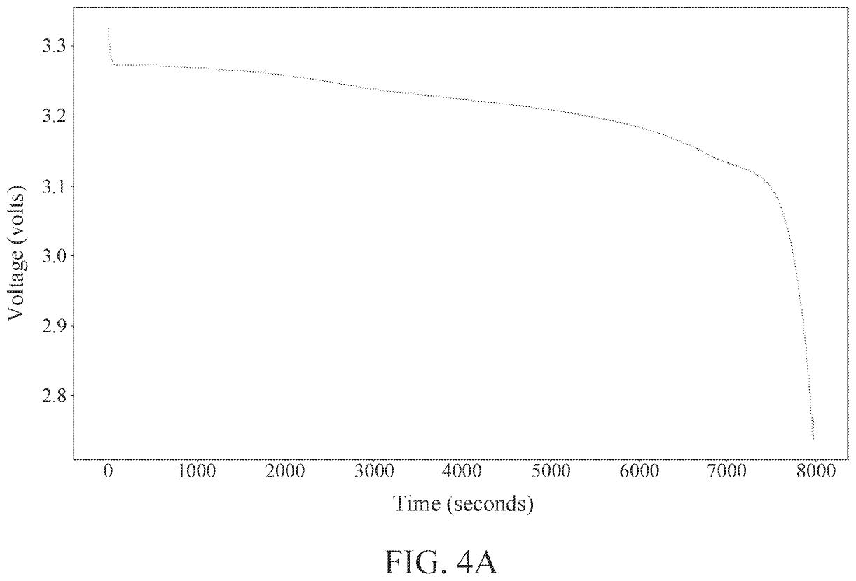

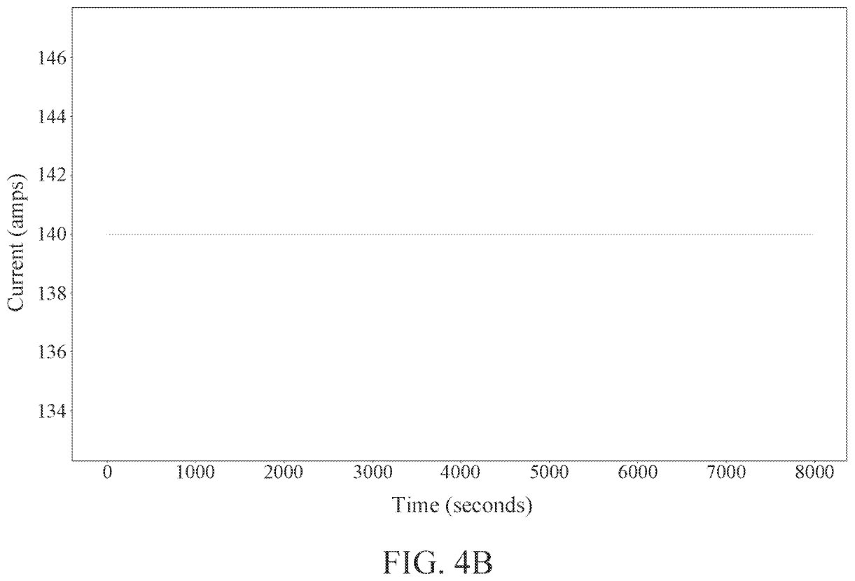

In step S31, the main battery management system 10 has the calibration device 20 provide a constant current (such as a charge and discharge rate of 0.1 C or 0.2 C) to one of the plurality of racks D₁-Dₙ, then the main battery management system 10 has one of the plurality of racks D₁-Dₙ discharge with a constant current (such as a charge and discharge rate of 0.1 C or 0.2 C) so as to measure the battery voltages of each of the battery packs PA₁-PAₙ (such as the battery voltages of a battery pack shown in FIG. 4A) and the battery currents (or called rack currents) of each of the battery packs PA₁-PAₙ (such as the battery currents of a battery pack shown in FIG. 4B) within one of the plurality of racks D₁-Dₙ via the voltage sensing module and the current sensing module 12.

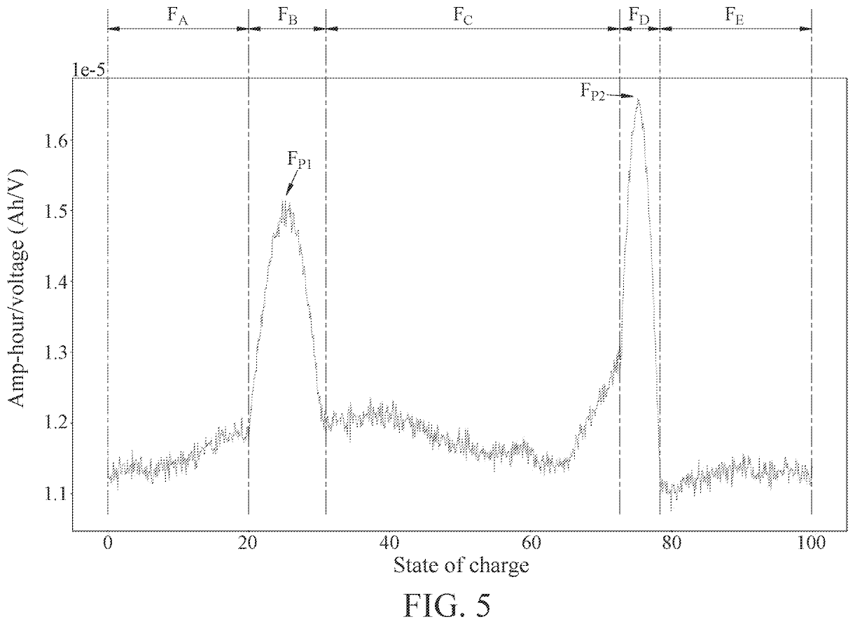

In step S32, the main battery management system 10 executes a battery feature value extraction algorithm based on the battery voltages and battery currents of each of the plurality of battery packs PA₁-PAₙ within one of the plurality of racks D₁-Dₙ, so as to obtain feature value data of each of the plurality of battery packs PA₁-PAₙ, wherein as shown in FIG. 5, the feature value data of a battery pack comprise a plurality of SOC feature values F_{A}, F_{B}, F_{C}, F_{D}, F_{E} and a plurality of peak feature values F_{P1}, F_{P2}.

In an embodiment, the battery feature value extraction algorithm can be a differential method so as to obtain the feature value data of each of the plurality of battery packs PA₁-PAₙ via the differential method, wherein the parameters of the differential method comprise operating voltage range, order (n) and capacity (Q), and the formulas (1), (2) of the differential method are as follows:

$$electrical capacitance ( C ) = \frac{dQ}{dV} = \frac{{\sum }_{n = 1}^{n - 1} \frac{( {Q}_{n + 1} - {Q}_{n} )}{n}}{{\sum }_{n = 1}^{n - 1} \frac{( {D}_{n + 1} - {D}_{n} )}{n}} \qquad ( 1 )$$

$$differential voltage ( D ) = \frac{dV}{dQ} = \frac{{\sum }_{n = 1}^{n - 1} \frac{( {V}_{n + 1} - {V}_{n} )}{n}}{{\sum }_{n = 1}^{n - 1} \frac{( {Q}_{n + 1} - {Q}_{n} )}{n}} \qquad ( 2 )$$

For instance, if taking a typical lithium iron phosphate battery as an example, the operating voltage range of the typical lithium iron phosphate battery can be 2.6 V to 3.45 V; if taking a lithium ternary battery as an example, the operating voltage range of the lithium ternary battery can be 2.4 V to 4.2 V; the order (n) is a positive integer and is related to the sampling time, and considering the calculation efficiency and time, when the sampling time is 1 second, the charge/discharge is 0.1 C to 0.5 C and the error is 1%, the order (n) range can be 72 to 360, and the order (n) can be adjusted according to the above principles; if taking a typical lithium iron phosphate battery as an example, the capacity (Q) is 280 Ah, which is calculated as the change in Q during charging/discharging, thus the capacity range can be 1 A/sec to 1008000 A/sec (280×3600) so as to calculate the feature value, wherein when dQ is the denominator value, dQ is not equal to 0.

In step S33, the main battery management system 10 predicts cycles of each of the plurality of battery packs PA₁-PAₙ according to the feature value data of each of the plurality of battery packs PA₁-PAₙ (i.e., the plurality of SOC feature values F_{A}-F_{E} and the plurality of peak feature values F_{P1}, F_{P2}) by using the battery aging correction model 10a.

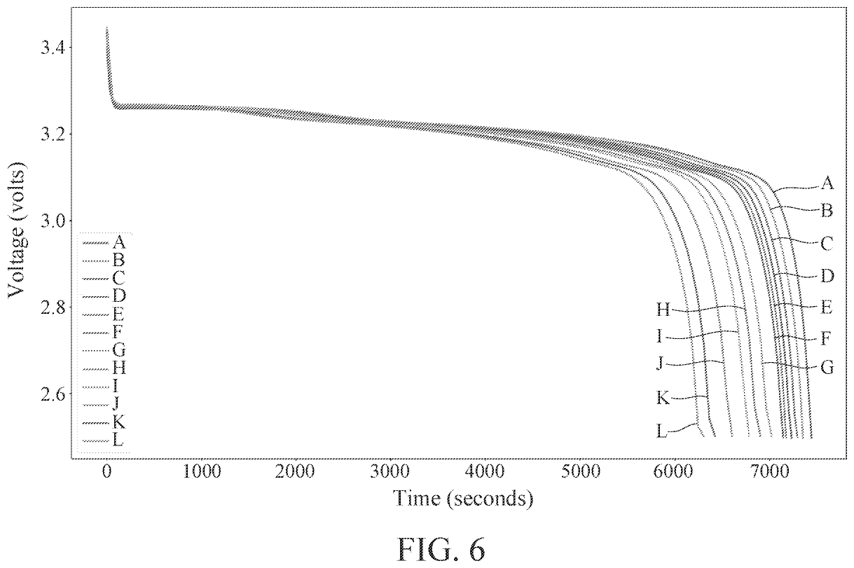

In an embodiment, the training data set of the battery aging correction model 10a uses the battery complete cycle data 1-4800 times, and includes actual voltage features at every time point (as shown in FIG. 6), wherein A to L shown in FIG. 6 refer to the number of battery complete cycles, and B>A, C>B, and so on; and the battery aging correction model 10a can use one of the machine learning model, support vector machine (SVM), XGBoost, convolutional neural network (CNN), or deep neural network (DNN).

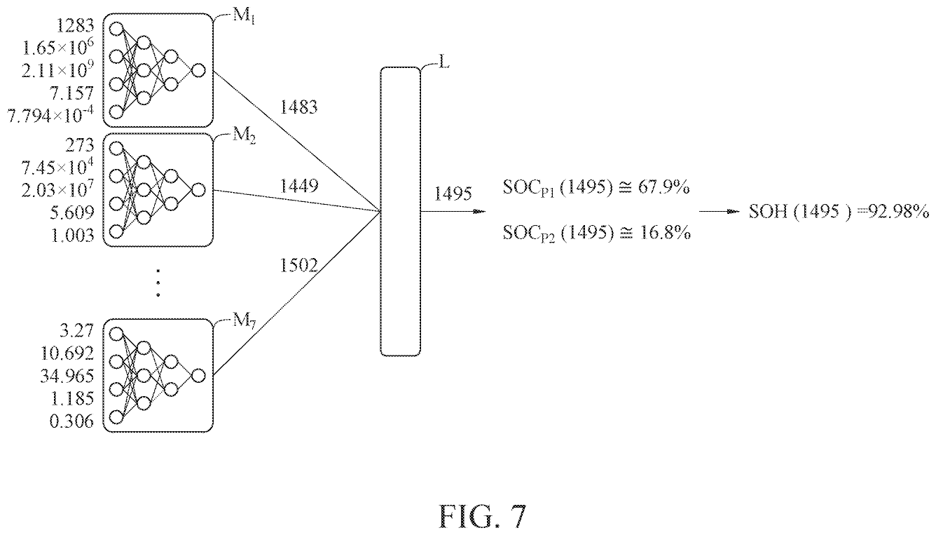

In an embodiment, as shown in FIG. 7, the battery aging correction model 10a is a deep neural network (DNN) model and comprises a plurality of prediction models M₁-M₇ and a vote vector L (e.g., an output layer) connected to the plurality of prediction models M₁-M₇, wherein corresponding plurality of training feature value data are obtained via the battery feature value extraction algorithm according to the plurality of battery complete cycle data within the training data set (as shown in FIG. 6), and the plurality of training feature value data also include the plurality of SOC feature values F_{A}-F_{E} and the plurality of peak feature values F_{P1}, F_{P2}, so that the battery aging correction model 10a conducts deep learning according to the plurality of training feature value data, such that the battery aging correction model 10a that has completed training can accurately predict the battery cycles of each of the plurality of battery packs PA₁-PAₙ.

For instance, as shown in FIG. 7, the plurality of training feature value data comprise a total of seven feature values including five SOC feature values F_{A}-F_{E} and two peak feature values F_{P1}, F_{P2}, and the seven groups of sub prediction models M₁-M₇ of the battery aging correction model 10a respectively correspond to the seven feature values, so as to train the corresponding sub prediction models M₁-M₇ based on the feature values respectively, wherein the plurality of sub prediction models M₁-M₇ will respectively input five SOC feature values F_{A}-F_{E}, two peak feature values F_{P1}, F_{P2}, and the exponential functions of square, cubic, natural logarithm and reciprocal of the feature values to conduct trainings. For instance, a sub prediction model M₁ will have the SOC feature value F_{A} and the exponential functions of square, cubic, natural logarithm and reciprocal thereof as inputs to conduct trainings. Therefore, the sub prediction models M₁-M₇ will predict the possible cycles via their corresponding feature values.

Then training the vote vector L for the vote mechanism, such that the vote vector L uses a regression method to obtain battery cycles from the plurality of possible cycles predicted by the plurality of prediction models M₁-M₇.

Specifically, the battery aging correction model 10a is based on the deep neural network (DNN), and its DNN algorithm formula (3) is as follows:

$$h ( {x}_{ij} , {w}_{ij} , {b}_{ij} ) = σ ( {x}_{ij} , {w}_{ij} , {b}_{ij} ) \\ regression analysis F = MSELoss ( {y}_{ij} , {y}_{r} ) \qquad ( 3 )$$

wherein h is the hidden layer; xᵢⱼ is the input value; yᵢⱼ is the estimated value; yᵣ is the true value; wᵢⱼ is the weighted matrix within the DNN algorithm; bᵢⱼ is the error within the DNN algorithm; σ is the nonlinear activation function, here a rectified linear unit (ReLU) is used as the activation function, and a sigmoid function is used in the last vote vector; F is the loss function within the DNN algorithm, and the regression analysis uses a mean-square error MSELoss(x) to calculate, while the classification method uses cross entropy to calculate; n is the sample size; and m is the classified number.

Moreover, when the deviation of the loss function is too large, an Adam optimization algorithm (adaptive moment estimation algorithm) is used for parameter optimization, wherein the Adam optimization algorithm maintains two momentum variables, namely the first-order moment estimation value (mean, m) and the second-order moment estimation value (variance, v) to estimate the first-order moment and the second-order moment of the gradient respectively for adaptively adjusting the learning rate. Furthermore, the initial learning rate a is to calculate the gradient and update the moment estimation value at every iteration step, the deviation is corrected when the moment estimation value exceeds the threshold, that is, the first-order moment estimation value m and the second-order moment estimation value v are divided by the correction to update the parameter value according to the first-order moment estimation value m, the second-order moment estimation value v and the learning rate a for convergence of the model parameters.

In step S34, the main battery management system 10 substitutes a first SOC regression formula (4) and a second SOC regression formula (5) (described in detail below) based on the battery cycles of each of the plurality of battery packs PA₁-PAₙ so as to calculate a first peak SOC value SOCₚ₁ and a second peak SOC value SOCₚ₂ of each of the plurality of battery packs PA₁-PAₙ.

In an embodiment, the first SOC regression formula (4) and the second SOC regression formula (5) are as follows:

$${SOC}_{p 1} ( C ) = {P}_{1} {C}^{6} + {P}_{2} {C}^{5} + {P}_{3} {C}^{4} + {P}_{4} {C}^{3} + {P}_{5} {C}^{2} + {P}_{6} C + {P}_{7} \qquad ( 4 )$$

$${SOC}_{p 2} ( C ) = {P}_{8} {C}^{6} + {P}_{9} {C}^{5} + {P}_{10} {C}^{4} + {P}_{11} {C}^{3} + {P}_{12} {C}^{2} + {P}_{13} C + {P}_{14} \qquad ( 5 )$$

wherein P₁-P₇ are coefficients of the first SOC regression formula; and P₈-P₁₄ are coefficients of the second SOC regression formula, wherein the regression parameters of the six-order polynomial formulas (i.e., the first and the second SOC regression formulas) are parameter-iterated by the least square method to calculate the curve with the smallest gap.

In step S35, the main battery management system 10 calculates the state of health (SOH) of each of the plurality of battery packs PA₁-PAₙ by using a battery SOH calibration formula (6) (described in detail below) based on the first peak SOC value SOCₚ₁ and the second peak SOC value SOCₚ₂ of each of the plurality of battery packs PA₁-PAₙ, and further updates the plurality of battery packs PA₁-PAₙ, thereby achieving the calibration of one of the plurality of racks D₁-Dₙ.

In an embodiment, the battery SOH calibration formula (6) is as follows:

$$SOH ( C ) = \frac{{Q}_{0} ( C )}{{Q}_{O} ( 1 )} = \frac{{\int }_{{F}_{p 2}}^{{F}_{p 1}} \frac{I ( t ) dt}{{SOC}_{p 1} - {SOC}_{p 2}}}{{Q}_{O} ( 1 )} \qquad ( 6 )$$

wherein Qₒ(C) is the total cycle charge (cycle N) of the tested battery; Qₒ(1) is the initial total charge (cycle 1) of the tested battery; Fₚ₁ is the first peak feature value; Fₚ₂ is the second peak feature value; I is the current of the rack; t is time; SOCₚ₁ is the first peak SOC value; and the SOCₚ₂ is the second peak SOC value.

The following example is an embodiment of the calibration system 1 for SOC and SOH in an energy storage system of the present disclosure, and is described with reference to FIG. 1 to FIG. 3. In addition, the same content between this embodiment and the aforementioned embodiment will not be described again.

In an embodiment, the operation status of the plurality of racks D₁-Dₙ (such as the first rack D₁, the second rack D₂, the third rack D₃ and the fourth rack D₄) obtained by the main battery management system 10 is shown in Table 1 below:

TABLE 1
operation status of racks

| | First rack D₁ | Second rack D₂ | Third rack D₃ | Fourth rack D₄ |
|---|---|---|---|---|
| Rack current | First rack current I₁ | Second rack current I₂ | Third rack current I₃ | Fourth rack current I₄ |
| SOC deviation of | First charge deviation | Second charge | Third charge deviation | Fourth charge |
| racks | ΔSOC₁ | deviation ΔSOC₂ | ΔSOC₃ | deviation ΔSOC₄ |

Then the main battery management system 10 checks whether the first rack D₁, the second rack D₂, the third rack D₃ and the fourth rack D₄ meet the auto-calibration conditions. For instance, the auto-calibration conditions include that the rack current is less than the current threshold Iₜₕ and the SOC deviation of the rack battery is greater than the charge deviation threshold ΔSOCₜₕ, wherein the SOC deviation of the rack battery refers to the difference between the battery (or cell) with the greatest SOC and the battery (or cell) with the least SOC in a rack, wherein the current threshold Iₜₕ and the charge deviation threshold ΔSOCₜₕ can be set to a certain threshold according to requirements so as to activate the auto-calibration conditions.

Therefore, the main battery management system 10 checks that the rack current I₂ of the second rack D₂ is less than the current threshold Iₜₕ and the second charge deviation ΔSOC₂ of the second rack D₂ is greater than the charge deviation threshold ΔSOCₜₕ. Hence, the main battery management system 10 checks that the second rack D₂ meets the auto-calibration conditions to have the second rack D₂ perform a disconnection strategy procedure, such that the second rack D₂ is disconnected from the power conversion system 30.

Next, the main battery management system 10 has the first switch 13a and the second switch 13b activate via the battery pack control module 11 within the second rack D₂, such that the calibration device 20 is connected in parallel with the second rack D₂, and the main battery management system 10 has the calibration device 20 provide a constant current with a charge and discharge rate of 0.1 C to the second rack D₂, then the main battery management system 10 has the second rack D₂ perform constant current discharge with a charge and discharge rate of 0.1 C, thereby measuring the battery voltages and battery currents (or called rack currents) of each of the battery packs PA₁-PAₙ of the second rack D₂.

The main battery management system 10 calculates the feature value data (as shown in FIG. 5) of each of the plurality of battery packs PA₁-PAₙ by the battery feature value extraction algorithm based on each of the battery packs PA₁-PAₙ of the second rack D₂.

Afterwards, the main battery management system 10 substitutes the plurality of SOC feature values F_{A}, F_{B}, F_{C}, F_{D}, F_{E} and the plurality of peak feature values F_{P1}, F_{P2} within the feature value data of each of the plurality of battery packs PA₁-PAₙ into the battery aging correction model 10a to predict the battery cycles of each of the plurality of battery packs PA₁-PAₙ, and substitutes the battery cycles of each of the plurality of battery packs PA₁-PAₙ into the first SOC regression formula (4) and the second SOC regression formula (5) to obtain the first peak SOC value SOCₚ₁ and the second peak SOC value SOCₚ₂ of each of the plurality of battery packs PA₁-PAₙ.

Moreover, the main battery management system 10 substitutes the first peak SOC value SOCₚ₁ and the second peak SOC value SOCₚ₂ of each of the plurality of battery packs PA₁-PAₙ into the battery SOH calibration formula (6), thereby calculating the state of health (SOH) of each of the plurality of battery packs PA₁-PAₙ, so as to update the plurality of battery packs PA₁-PAₙ and achieve the calibration of the second rack D₂, and further to have the second rack D₂ connect to the power conversion system 30 in parallel.

For instance, as shown in FIG. 7, taking the battery pack PA₁ within the second rack D₂ as an example, the main battery management system 10 substitutes the feature value data of the battery pack PA₁ into the battery aging correction model 10a, and predicts the battery cycles (cycle=1495) of the battery pack PA₁, and then substitutes the battery cycles of the battery pack PA₁ into the first SOC regression formula (4) and the second SOC regression formula (5) to obtain the first peak SOC value SOCₚ₁ of the battery pack PA₁ (SOCₚ₁ (C=1495)=67.9%) and the second peak SOC value SOCₚ₂ of the battery pack PA₁ (SOCₚ₂ (C=1495)=16.8%), wherein the first SOC regression formula (4) is SOCₚ₁ (C)=0.8067C⁶−3.0139C⁵+2.4006C⁴+1.7541C³−1.9749C²+2.9155C+67.9688, and the second SOC regression formula (5) is SOCₚ₂ (C)=0.1692C⁶−0.2908C⁵−0.6857C⁴+1.4107C³−0.67C²+1.4081C+16.8188.

Furthermore, the first peak SOC value SOCₚ₁=67.9% and the second peak SOC value SOCₚ₂=16.8% are substituted into the battery SOH calibration formula (6) to obtain

$$SOH ( C = 1495 ) = \frac{( 140 \times \frac{3421}{3600} / ( 67.9 \% - 16.8 \% ) )}{280} = \frac{260.35}{280} = 92.98 \% ,$$

thereby updating the battery pack PA₁.

To sum up, in the calibration system and method for SOC and SOH in an energy storage system according to the present disclosure, the main battery management system determines whether the plurality of racks meet the auto-calibration conditions, wherein when one of the plurality of racks meets the auto-calibration conditions, the main battery management system has one of the plurality of racks disconnect from the power, and obtains the feature value data of each battery pack by using the battery feature value extraction algorithm, then predicts the battery cycles of each of the plurality of battery packs via the battery aging correction model, thereby calculating the corresponding SOH based on the battery cycles of each of the plurality of battery packs, so as to update the plurality of battery packs of one of the plurality of racks.

Therefore, compared to the existing technology that uses the conventional methods such as Coulomb counting to calibrate the state of charge (SOC) of the battery (thereby causing errors in the calibration result) or requires the battery to be evaluated in a stable state in order to improve the detection accuracy, the present disclosure can accurately obtain the feature value data of each battery pack (including the SOC feature values and the peak feature values) via the battery feature value extraction algorithm, and further uses artificial intelligence method to accurately predict the battery cycles of each of the plurality of battery packs via the battery aging correction model that is based on a neural network. Therefore, the present disclosure can accurately and quickly calculate the state of charge (SOC) and the state of health (SOH) without requiring the battery to be in a stable state, such that maintenance personnel can clearly comprehend the status of each rack, thereby improving the efficiency of power management.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A calibration system for state of charge (SOC) and state of health (SOH) in an energy storage system, the calibration system comprising:
a power conversion system configured for providing power;
a plurality of racks electrically connected to the power conversion system and obtaining the power from the power conversion system, wherein each of the plurality of racks comprises a plurality of battery packs; and
a main battery management system communicatively connected to the plurality of racks and having a battery aging correction model, wherein when the main battery management system determines that one of the plurality of racks meets auto-calibration conditions, the main battery management system has the one of the plurality of racks disconnect from the power conversion system and obtains battery voltages and battery currents of each of the plurality of battery packs of the one of the plurality of racks,
wherein the main battery management system executes a battery feature value extraction algorithm to obtain corresponding feature value data based on the battery voltages and the battery currents of each of the plurality of battery packs, so as to predict battery cycles of each of the plurality of battery packs based on the feature value data of each of the plurality of battery packs via the battery aging correction model, thereby calculating a corresponding SOH value based on the battery cycles of each of the plurality of battery packs and updating the plurality of battery packs.

2. The calibration system of claim 1, further comprising: a calibration device configured for providing a constant current, wherein after the one of the plurality of racks is disconnected from the power conversion system, the main battery management system has the one of the plurality of racks electrically connect to the calibration device, such that the one of the plurality of racks obtains the constant current from the calibration device.

3. The calibration system of claim 1, wherein the feature value data of each of the plurality of battery packs comprise a plurality of SOC feature values and a plurality of peak feature values.

4. The calibration system of claim 3, wherein the battery aging correction model predicts a plurality of possible cycles of each of the plurality of battery packs respectively based on the plurality of SOC feature values and the plurality of peak feature values of each of the plurality of battery packs, and further selects the battery cycles of each of the plurality of battery packs from the plurality of possible cycles of each of the plurality of battery packs.

5. The calibration system of claim 1, wherein the main battery management system calculates a plurality of peak SOC values of each of the plurality of battery packs based on the battery cycles of each of the plurality of battery packs, and further calculates SOH values of each of the plurality of battery packs based on the plurality of peak SOC values of each of the plurality of battery packs.

6. The calibration system of claim 1, wherein the battery aging correction model is a neural network model.

7. A calibration method for state of charge (SOC) and state of health (SOH) in an energy storage system, the calibration method comprising:
when a main battery management system determines that one of a plurality of racks meets auto-calibration conditions, disconnecting the one of the plurality of racks disconnect from a power conversion system by the main battery management system to obtain battery voltages and battery currents of each of the plurality of battery packs of the one of the plurality of racks;
Executing a battery feature value extraction algorithm by the main battery management system to obtain corresponding feature value data based on the battery voltages and the battery currents of each of the plurality of battery packs;
Predicting battery cycles of each of the plurality of battery packs by the main battery management system based on the feature value data of each of the plurality of battery packs via a battery aging correction model; and
Calculating a corresponding SOH value based on the battery cycles of each of the plurality of battery packs, and updating the plurality of battery packs by the main battery management system.

8. The calibration method of claim 7, further comprising: after the one of the plurality of racks is disconnected from the power conversion system, electrically connecting the one of the plurality of racks by the main battery management system to a calibration device, such that the one of the plurality of racks obtains a constant current from the calibration device.

9. The calibration method of claim 7, wherein the feature value data of each of the plurality of battery packs comprise a plurality of SOC feature values and a plurality of peak feature values.

10. The calibration method of claim 9, further comprising: by the battery aging correction model, predicting a plurality of possible cycles of each of the plurality of battery packs respectively based on the plurality of SOC feature values and the plurality of peak feature values of each of the plurality of battery packs, and further selecting the battery cycles of each of the plurality of battery packs from the plurality of possible cycles of each of the plurality of battery packs.

11. The calibration method of claim 7, further comprising: by the main battery management system, calculating a plurality of peak SOC values of each of the plurality of battery packs based on the battery cycles of each of the plurality of battery packs, and further calculating SOH values of each of the plurality of battery packs based on the plurality of peak SOC values of each of the plurality of battery packs.

12. The calibration method of claim 7, wherein the battery aging correction model is a neural network model.
